(19) United States
(12) Patent Application Publication
(10) Pub. No.: US 2019/0140588 A1
(43) Pub. Date: May 9, 2019

(54) CONTROL METHOD OF PHOTOVOLTAIC ELEMENT

(71) Applicants: KABUSHIKI KAISHA TOSHIBA, Tokyo (JP); TOSHIBA TEC KABUSHIKI KAISHA, Tokyo (JP)

(72) Inventor: Takeshi Watanabe, Yokohama (JP)

(21) Appl. No.: 16/240,922

(22) Filed: Jan. 7, 2019

Related U.S. Application Data
(62) Division of application No. 15/633,867, filed on Jun. 27, 2017.
Application No. 15/633,867 is a division of application No. 14/741,692, filed on Jun. 17, 2015, now abandoned.

(51) Int. Cl. H02S 40/22; G02F 1/163; H02S 20/26; G03G 15/00; G02F 1/133; G02F 1/167; E06B 9/24

(52) U.S. Cl. CPC H02S 40/22; G02F 1/163; H02S 20/26; H01L 51/4253; G02F 1/13306; G02F 1/167; E06B 9/24; G03G 15/80

(57) ABSTRACT

A control method of photovoltaic element involves preparing a photovoltaic element with a photoelectromotive force part having a light transmitting property and generating an electromotive force by light irradiation, light transmittances of a first transmitting member and a second transmitting member being electrically changed; acquiring a user instruction for the light transmittance of the whole photovoltaic element; adjusting the light transmittance at a light emission side in the first transmitting member and the second transmitting member according to the user instruction; measuring change in power generation amount while changing the respective light transmittances; and setting the respective light transmittances to values corresponding to the maximum power generation amount.

### CROSS-REFERENCE TO RELATED APPLICATIONS

This application is a Division of application Ser. No. 15/633,867 filed on Jun. 27, 2017, which is a Division of application Ser. No. 14/741,692 filed on Jun. 17, 2015, the entire contents of both of which are incorporated herein by reference.

### FIELD

Embodiments described herein relate generally to a control method of a photovoltaic element.

### BACKGROUND

There is a photoelectromotive force element which performs power generation and shading while changing power generation amount and transmittance to sun light. The photoelectromotive force element includes a solar cell having a light transmitting property and an element whose light transmittance changes. The photoelectromotive force element is arranged on a window of a building or the like, generates power by sun light, and adjusts natural lighting into the building. However, when power generation is performed by indoor illumination light, the transmittance of an element arranged closer to the indoor side than the solar cell is required to be increased. If the transmittance of the element is increased at night or the like, there is a possibility that desired screenability can not be secured.

### DESCRIPTION OF THE DRAWINGS

FIG. 1 is a block diagram showing a whole configuration example of a photovoltaic system of an embodiment.

FIG. 2 is a block diagram showing an configuration example of a controller of the embodiment.

FIG. 3 is a sectional view schematically showing a configuration example of a photovoltaic element of the embodiment.

FIG. 4 is a sectional view schematically showing a state change according to change in transmittance of an electrochromic element of the embodiment.

FIG. 5 is a flowchart showing an operation example of the photovoltaic system of the embodiment.

FIG. 6 is a block diagram showing a whole configuration example of a photovoltaic system of a modified example of the embodiment.

FIG. 7 is a view schematically showing a whole configuration example of an image forming apparatus of the modified example of the embodiment.

FIG. 8 is a block diagram showing a configuration example of the image forming apparatus of the modified example of the embodiment.

### DETAILED DESCRIPTION

In general, according to one embodiment, a photovoltaic element includes a photoelectromotive force part, a first transmitting member and a second transmitting member. The photoelectromotive force part has a light transmitting property and generates an electromotive force by light irradiation. The first transmitting member and the second transmitting member are arranged at both sides of the photoelectromotive force part in a thickness direction, and have light transmittances electrically changed.

Hereinafter, a photovoltaic system 100 and a photovoltaic element 400 according to an embodiment will be described with reference to the drawings. Incidentally, in the respective drawings, the same components are denoted by the same reference numerals.

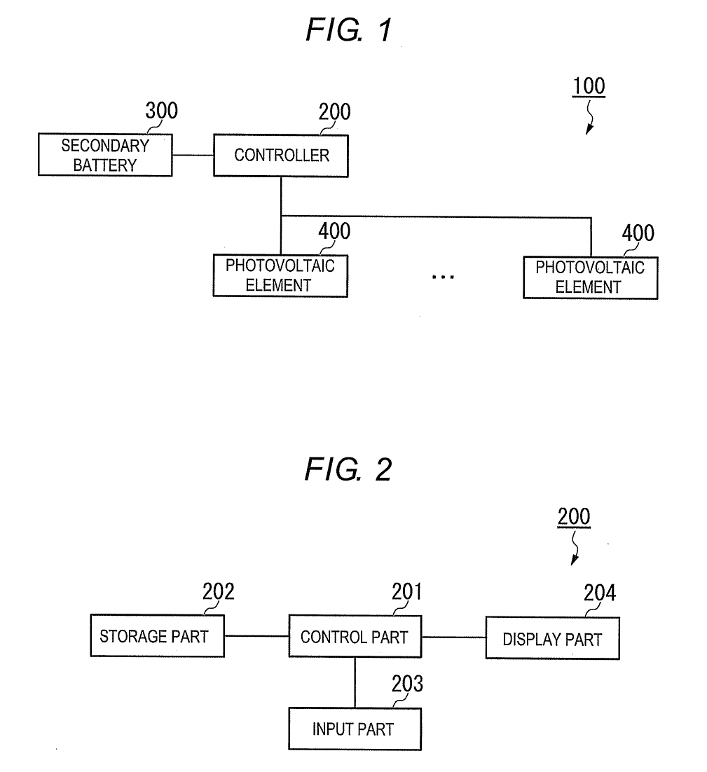

FIG. 1 is a block diagram showing a whole configuration example of the photovoltaic system of the embodiment. As shown in FIG. 1, the photovoltaic system 100 includes a controller 200, a secondary battery 300 and at least one photovoltaic element 400.

FIG. 2 is a block diagram showing a configuration example of the controller of the embodiment. As shown in FIG. 2, the controller 200 includes a control part 201, a storage part 202, an input part 203 and a display part 204. The control part 201 includes a CPU, a ROM and a RAM. The control part 201 controls power generation amount and light transmittance of the photovoltaic element 400. The storage part 202 stores various information required for control of the photovoltaic element 400. The input part 203 includes plural buttons and switches, and outputs a signal according to an input operation of a user. The display part 204 displays various information relating to the power generation amount and light transmittance of the photovoltaic element 400.

The secondary battery 300 applies a DC voltage, which is required to change the light transmittance during dimming of the photovoltaic element 400, to the photovoltaic element 400. The secondary battery 300 stores generated power during power generation of the photovoltaic element 400.

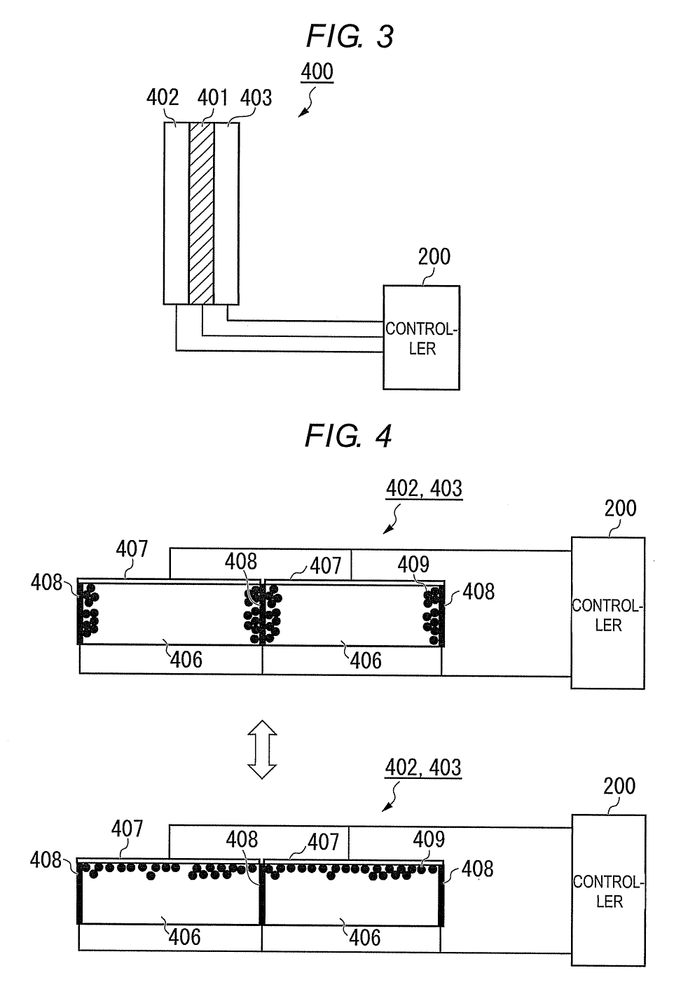

FIG. 3 is a sectional view schematically showing a configuration example of the photovoltaic element 400 of the embodiment. The shape of the photovoltaic element 400 is formed into a sheet shape. The photovoltaic element 400 is arranged, for example, on a window of a building, a moving body or the like. As shown in FIG. 3, the photovoltaic element 400 includes a photoelectromotive force part 401, a first transmitting member 402 and a second transmitting member 403.

The photoelectromotive force part 401 has sensibility to a wavelength range including wavelengths of sun light and illumination light. The illumination light is light emitted by various illumination devices such as an LED illuminating lamp, a fluorescent lamp and a bulb. The photoelectromotive force part 401 is, for example, an organic thin film solar cell. The organic thin film solar cell includes a first transparent substrate, a first transparent electrode, a hole transport layer, an active layer, a hole block layer, a second transparent electrode, and a second transparent substrate, which are sequentially stacked. The first transparent substrate and the second transparent substrate are, for example, a glass substrate and a resin substrate having light transmitting properties. The first transparent electrode and the second transparent electrode are, for example, ITO (Indium Tin Oxide) or the like. The hole transport layer is, for example, water-dispersible polythiophene derivative (PEDOT-PSS) or the like. The active layer is formed from an organic solvent in which condensed ring system polymer as a p-type organic semiconductor and fullerene derivative as an n-type organic semiconductor dissolve. The condensed ring system polymer as the p-type organic semiconductor is, for example, PTB7 (bithiophene benzodithiophene fluoride). The fullerene derivative is, for example, C70 fullerene derivative. The active layer is formed by, for example, a spin coater. The hole block layer is, for example, an inorganic oxide film. The organic thin film solar cell generates power in such a way that a light exciton diffusing from the active layer causes charge separation on a pn junction interface, and an electron and a hole move to respective electrodes.

The first transmitting member 402 and the second transmitting member 403 sandwich the photoelectromotive force part 401 from both sides in the thickness direction. Light transmittances of the first transmitting member 402 and the second transmitting member 403 are electrically changed independently of each other. Each of the first transmitting member 402 and the second transmitting member 403 is, for example, an electrochromic element or an electronic paper element. The electrochromic element exhibits reversible light transmittance change by an electrochemical oxidation-reduction reaction of a chemical material. A typical electrochromic element has a configuration in which tungsten oxide or tungsten-nickel oxide is sandwiched between transparent electrode plates. In the electrochromic element, a positively charged lithium ion moves to an electrochromic layer by DC voltage application and the layer is colored blue, and when a current is not applied, the layer becomes transparent. On the other hand, although there is also an electronic paper element using an electrochromic element, in the embodiment, a particle movement type electronic paper element will be described as an example.

FIG. 4 is a sectional view schematically showing a state change according to change in transmittance of the electronic paper element of the embodiment. As shown in FIG. 4, an electronic paper element 405 includes a transparent cell 406, a transparent electrode 407, a wall surface electrode 408 and a colored particle 409. The transparent cell 406 includes the colored particle 409 moving in the inside. The transparent electrode 407 is arranged at an end of the transparent cell 406 in the thickness direction. The wall surface electrode 408 is arranged at a wall part dividing the transparent cell 406. The color of the colored particle 409 is, for example, white. The light transmittance of the electronic paper element 405 in the thickness direction is changed according to an electric field generated in the transparent cell 406 by electric power applied to each of the transparent electrode 407 and the wall surface electrode 408. When the colored particle 409 is attracted to the transparent electrode 407 by the electric field in the transparent cell 406, the light transmittance of the electronic paper element 405 decreases. As the light transmittance of the electronic paper element 405 decreases, the light reflectivity of the electronic paper element 405 is changed in an increasing tendency. When the colored particle 409 is attracted to the wall surface electrode 408 by the electric field in the transparent cell 406, the light transmittance of the electronic paper element 405 increases. As the light transmittance of the electronic paper element 405 increases, the light reflectivity of the electronic paper element 405 is changed in a decreasing tendency. The electronic paper element 405 keeps the state of the colored particle 409 and the light transmittance without requiring continuous power supply to the transparent electrode 407 and the wall surface electrode 408.

In the photovoltaic element 400, when the light transmittance of the first transmitting member 402 increases, power generation amount by light incident from the first transmitting member 402 side increases. In the photovoltaic element 400, when the light reflectivity of the second transmitting member 403 increases, the power generation amount by the light incident from the first transmitting member 402 side increases.

In the photovoltaic element 400, when the light transmittance of the second transmitting member 403 increases, power generation amount by light incident from the second transmitting member 403 side increases. In the photovoltaic element 400, when the light reflectivity of the first transmitting member 402 increases, the power generation amount by the light incident from the second transmitting member 403 side increases.

In the photovoltaic element 400, when the light transmittance of at least one of the first transmitting member 402 and the second transmitting member 403 increases, the light transmittance of the whole photovoltaic element 400 increases. In the photovoltaic element 400, when the light transmittance of at least one of the first transmitting member 402 and the second transmitting member 403 decreases, the light transmittance of the whole photovoltaic element 400 decreases. In the photovoltaic element 400, when the light transmittances of the first transmitting member 402 and the second transmitting member 403 change in tendencies opposite to each other, the light transmittance of the whole photovoltaic element 400 is kept constant.

Hereinafter, an operation example of the photovoltaic system 100 will be described.

The control part 201 automatically controls the photovoltaic element 400 according to control pattern data stored in the storage part 202 and a signal of user instruction outputted from the input part 203.

The control part 201 controls the photovoltaic element 400, which is arranged, for example, on a window of a building while the first transmitting member 402 is located at an outdoor side and the second transmitting member 403 is located at an indoor side, according to the control pattern. In the fine daytime when outdoor light is more intense than indoor light, the control part 201 increases the light transmittance of the first transmitting member 402 and decreases the light transmittance of the second transmitting member 403. The indoor light is light emitted by indoor illumination devices. The outdoor light is sun light or the like. In the night when the indoor light is more intense than the outdoor light, the control part 201 decreases the light transmittance of the first transmitting member 402 and increases the light transmittance of the second transmitting member 403.

The control part 201 controls the photovoltaic element 400, which is arranged, for example, on a window of a building while the first transmitting member 402 is located at an outdoor side and the second transmitting member 403 is located at an indoor side, according to the user instruction. If the light transmittance of the whole photovoltaic element 400 is designated for natural lighting or screening by the user, the control part 201 maximizes power generation amount while keeping the designated light transmittance.

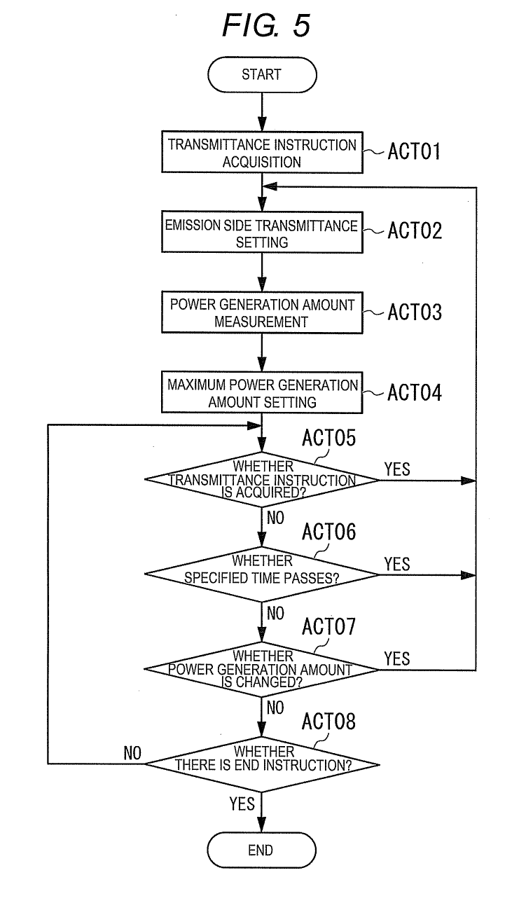

FIG. 5 is a flowchart showing an operation example of the photovoltaic system of the embodiment. As shown in FIG. 5, the control part 201 acquires, from the input part 203, a user instruction for the light transmittance of the whole photovoltaic element 400 (ACT01). The user instruction is, for example, an instruction for the light transmittance to the outdoor light incident on the indoor side from the outdoor side for natural lighting in the daytime. The user instruction is, for example, an instruction for the light transmittance to the indoor light emitting to the outdoor side from the indoor side for screening in the night.

The control part 201 adjusts the light transmittance at the light emission side in the first transmitting member 402 and the second transmitting member 403 according to the user instruction from the input part 203 (ACT02). The control part 201 adjusts the light transmittance at the light emission side from the state of the photovoltaic element 400 when the user instruction is acquired. The control part 201 makes the light transmittance of the whole photovoltaic element 400 coincident with the user instruction by adjusting the light transmittance at the light emission side. When the outdoor light is more intense than the indoor light in, for example, the daytime, the control part 201 adjusts the light transmittance of the indoor side second transmitting member 403. When the indoor light is more intense than the outdoor light in, for example, the night, the control part 201 adjusts the light transmittance of the outdoor side first transmitting member 402.

The control part 201 changes the respective light transmittances of the first transmitting member 402 and the second transmitting member 403 while keeping the light transmittance of the whole photovoltaic element 400 constant. The control part 201 measures change in power generation amount while changing the respective light transmittances of the first transmitting member 402 and the second transmitting member 403 (ACT03). The control part 201 changes the light transmittances of the first transmitting member 402 and the second transmitting member 403 in tendencies opposite to each other in order to keep the light transmittance of the whole photovoltaic element 400 constant. For example, the control part 201 decreases the light transmittance of the first transmitting member 402 and increases the light transmittance of the second transmitting member 403. For example, the control part 201 increases the light transmittance of the first transmitting member 402 and decreases the light transmittance of the second transmitting member 403. The control part 201 stores, in the storage part 202, the change in power generation amount according to the change in the respective light transmittances of the first transmitting member 402 and the second transmitting member 403. The control part 201 stores, in the storage part 202, data of correspondence relation between different combinations of the respective light transmittances of the first transmitting member 402 and the second transmitting member 403 and the power generation amount.

The control part 201 acquires the respective light transmittances of the first transmitting member 402 and the second transmitting member 403 corresponding to the maximum power generation amount from the data stored in the storage part 202. The control part 201 sets the respective light transmittances of the first transmitting member 402 and the second transmitting member 403 to values corresponding to the maximum power generation amount (ACT04).

The control part 201 determines whether a new user instruction for the light transmittance of the whole photovoltaic element 400 is acquired from the input part 203 (ACT05).

If the determination result is “NO” (ACT05: NO), the control part 201 advances the processing to ACT06.

On the other hand, if the determination result is “YES” (ACT05: YES), the control part 201 returns the processing to ACT02.

The control part 201 determines whether a specified time passes after the respective light transmittances of the first transmitting member 402 and the second transmitting member 403 are adjusted most recently (ACT06).

If the determination result is “NO” (ACT06: NO), the control part 201 advances the processing to ACT07.

On the other hand, if the determination result is “YES” (ACT06: YES), the control part 201 returns the processing to ACT02.

The control part 201 determines whether the power generation amount of the photovoltaic element 400 changes more than a specified value (ACT07).

If the determination result is “NO” (ACT07: NO), the control part 201 advances the processing to ACT08.

On the other hand, if the determination result is “YES” (ACT07: YES), the control part 201 returns the processing to ACT02.

The control part 201 determines whether an end instruction of the auto adjustment for the respective light transmittances of the first transmitting member 402 and the second transmitting member 403 is acquired from the input part 203 (ACT08).

If the determination result is “NO” (ACT08: NO), the control part 201 returns the processing to ACT05.

On the other hand, if the determination result is “YES” (ACT08: YES), the control part 201 ends the series of processing.

Since the photovoltaic element 400 of the embodiment described above includes the first transmitting member 402 and the second transmitting member 403, the light transmittance can be set at both sides of the photoelectromotive force part 401 in the thickness direction. Since the first transmitting member 402 and the second transmitting member 403 are provided, the power generation amount and the light transmittance can be set appropriately for the lights incident from both sides of the photoelectromotive force part 401 in the thickness direction. Since the first transmitting member 402 and the second transmitting member 403 whose light transmittances are electrically changed independently of each other are provided, the power generation amount can be maximized while the constant light transmittance is kept as a whole. Since the photoelectromotive force part 401 is provided which has sensitivity in the wavelength range including the wavelengths of the sun light and the illumination light, natural lighting and screening can be performed while power generation is performed at the window of the building, the moving body and the like. Since the photoelectromotive force part 401 of the organic thin film solar cell is provided, the desired power generation efficiency for the wavelength range including the wavelengths of the sun light and the illumination light can be secured. Since the first transmitting member 402 and the second transmitting member 403 of the electrochromic element or the electronic paper element are provided, the light transmittances can be electrically changed independently of each other.

Since the photovoltaic system 100 of the embodiment described above includes the control part 201 to control the light transmittance of the photovoltaic system 400, the power generation efficiency can be improved. Since the control part 201 is provided which adjusts the light transmittance at the light emission side in the first transmitting member 402 and the second transmitting member 403, a decrease in power generation efficiency can be suppressed. Since the control part 201 is provided which changes the light transmittances of the first transmitting member 402 and the second transmitting member 403 while keeping the light transmittance of the photovoltaic element 400 constant, the power generation efficiency can be maximized. Since the control part 201 is provided which sets the light transmittances of the first transmitting member 402 and the second transmitting member 403 according to the user instruction, the user instruction can be quickly dealt with. Since the control part 201 is provided which sets the light transmittance again after the specified time passes after the light transmittance of the photovoltaic element 400 is set most recently, the power generation efficiency can be optimized at a proper timing. Since the control part 201 is provided which sets the light transmittance again when the power generation amount of the photovoltaic element 400 changes more than the specified value, the power generation efficiency can be optimized. Since the input part 203 is provided which inputs the user instruction to the control part 201, the user instruction can be quickly dealt with. Since the input part 203 is provided which outputs the user instruction to the photovoltaic element 400 provided on the window of the building or the moving body, the intention of the user can be made to be suitably reflected on natural lighting and screening.

Hereinafter, modified examples of the embodiment will be described.

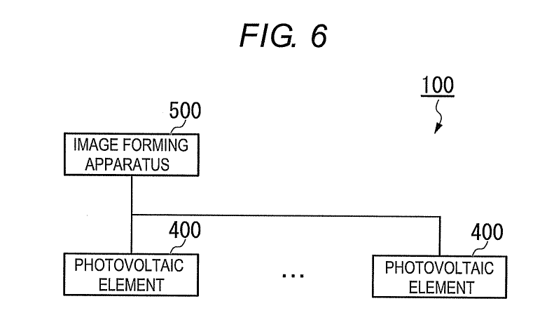

FIG. 6 is a view schematically showing a whole configuration example of a photovoltaic system 100 of a modified example of the embodiment. As shown in FIG. 6, the photovoltaic system 100 of the modified example includes an image forming apparatus 500 and at least one photovoltaic element 400. The photovoltaic element 400 is provided on, for example, a window of a building in which the image forming apparatus 500 is disposed.

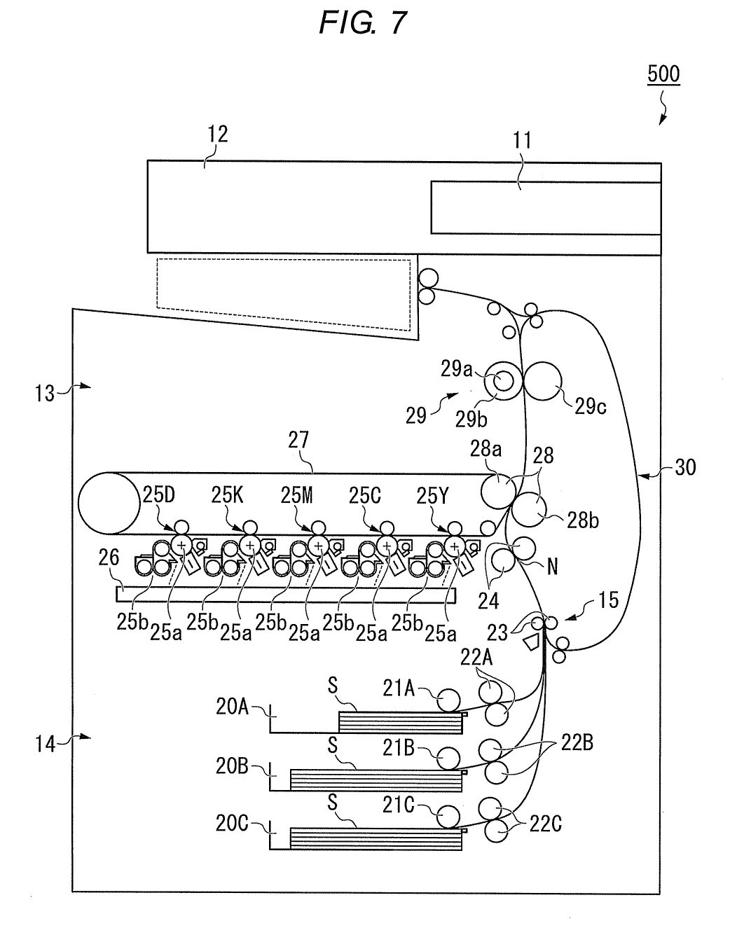

FIG. 7 is a view schematically showing a whole configuration example of the image forming apparatus 500 of the modified example of the embodiment. As shown in FIG. 7, the image forming apparatus 500 includes a control panel 11, a scanner part 12, a printer part 13, a sheet containing part 14 and a conveyance part 15.

The scanner part 12 reads image information of a copy object as light brightness and darkness. The scanner part 12 outputs the read image information to the printer part 13.

The printer part 13 forms an output image (hereinafter referred to as a toner image) by a developer such as toner based on the image information from the scanner part 12 or the outside. The printer part 13 transfers the toner image onto the surface of a sheet S. The printer part 13 applies heat and pressure to the toner image on the surface of the sheet S, and fixes the toner image to the sheet S.

The sheet containing part 14 supplies the sheets S one by one to the printer part 13 in synchronization with timing when the printer part 13 forms the toner image. The sheet containing part 14 includes plural paper feed cassettes 20A, 20B and 20C. Each of the paper feed cassettes 20A, 20B and 20C contains the sheets S of a previously set size and kind. The paper feed cassettes 20A, 20B and 20C respectively include pickup rollers 21A, 21B and 21C. The respective pickup rollers 21A, 21B and 21C take out the sheets S one by one from the respective paper feed cassettes 20A, 20B and 20C. The pickup rollers 21A, 21B and 21C supply the taken-out sheets S to the conveyance part 15.

The conveyance part 15 includes a conveyance roller 23 and a register roller 24. The conveyance part 15 conveys the sheet S supplied from the pickup rollers 21A, 21B and 21C to the register roller 24. The register roller 24 conveys the sheet S at timing when the printer part 13 transfers the toner image to the sheet S. The conveyance roller 23 causes the leading end of the sheet S in the conveyance direction to abut on a nip N of the register roller 24. The conveyance roller 23 adjusts the position of the leading end of the sheet S in the conveyance direction by bending the sheet S. The register roller 24 aligns the leading end of the sheet S sent from the conveyance roller 23 at the nip N, and then conveys the sheet S to the transfer part 28 side described later.

The printer part 13 includes plural image forming parts 25Y, 25M, 25C, 25K and 25D, an exposure part 26, an intermediate transfer belt 27, a transfer part 28 and a fixing unit 29.

Each of the plural image forming parts 25Y, 25M, 25C, 25K and 25D forms a toner image to be transferred to the sheet S. Each of the plural image forming parts 25Y, 25M, 25C, 25K and 25D includes a photoconductive drum (image carrier) 25a. The plural image forming parts 25Y, 25M, 25C, 25K and 25D include developing devices 25b to selectively supply toners to the surfaces of the respective photoconductive drums 25a. The developing devices 25b contain non-decolorable toners of yellow, magenta, cyan and black and a decolorable toner. The decolorable toner discolors at a temperature higher than a specified decolorable temperature.

The exposure part 26 faces the photoconductive drums 25a of the respective image forming parts 25Y, 25M, 25C, 25K. The exposure part 26 irradiates laser light based on the image information to the surfaces of the photoconductive drums 25a of the respective image forming parts 25Y, 25M, 25C, 25K and 25D. The exposure part 26 develops electrostatic latent images on the surfaces of the photoconductive drums 25a of the respective image forming parts 25Y, 25M, 25C, 25K and 25D. The image forming part 25Y develops the electrostatic latent image formed by the laser light from the exposure part 26 with yellow toner. The image forming part 25Y forms a yellow toner image on the surface of the photoconductive drum 25a. The image forming part 25M develops the electrostatic latent image formed by the laser light from the exposure part 26 with magenta toner. The image forming part 25M forms a magenta toner image on the surface of the photoconductive drum 25a. The image forming part 25C develops the electrostatic latent image formed by the laser light from the exposure part 26 with cyan toner. The image forming part 25C forms a cyan toner image on the surface of the photoconductive drum 25a. The image forming part 25K develops the electrostatic latent image formed by the laser light from the exposure part 26 with black toner. The image forming part 25K forms a black toner image on the surface of the photoconductive drum 25a. The image forming part 25D develops the electrostatic latent image formed by the laser light from the exposure part 26 with decolorable toner. The image forming part 25D forms a decolorable toner image on the surface of the photoconductive drum 25a.

The respective image forming parts 25Y, 25M, 25C, 25K and 25D transfer (primary transfer) the toner images on the surfaces of the photoconductive drums 25a onto the intermediate transfer belt 27. The respective image forming parts 25Y, 25M, 25C, 25K and 25D apply transfer biases to the toner images at respective primary transfer positions. The respective image forming parts 25Y, 25M, 25C, 25K overlap and transfer the toner images of the respective colors to the intermediate transfer belt 27. The respective image forming parts 25Y, 25M, 25C, 25K form a color toner image on the intermediate transfer belt 27.

The transfer part 28 transfers the charged toner image on the intermediate transfer belt 27 onto the surface of the sheet S at a secondary transfer position. The secondary transfer position is a position where a support roller 28a and a secondary transfer roller 28b face each other. The transfer part 28 applies a transfer bias corresponding to a transfer current to the secondary transfer position. The transfer part 28 transfers the toner image on the intermediate transfer belt 27 to the sheet S by the transfer bias.

The fixing unit 29 includes a heat roller 29b having a built-in heating part 29a, and a pressure roller 29c. The pressure roller 29c is in press contact with the fixing belt which is heated by the heat controller 29b. The fixing unit 29 fixes the toner image on the surface of the sheet S to the sheet S by heat and pressure applied to the sheet S.

The printer part 13 includes a reverse unit 30. The reverse unit 30 reverses the sheet S discharged from the fixing unit 29 by switching back. The reverse unit 30 conveys the sheet S after reversal to the front of the register roller 24 again. The reverse unit 30 reverses the sheet S in order to form an image on the back surface of the sheet S subjected to the fixing process.

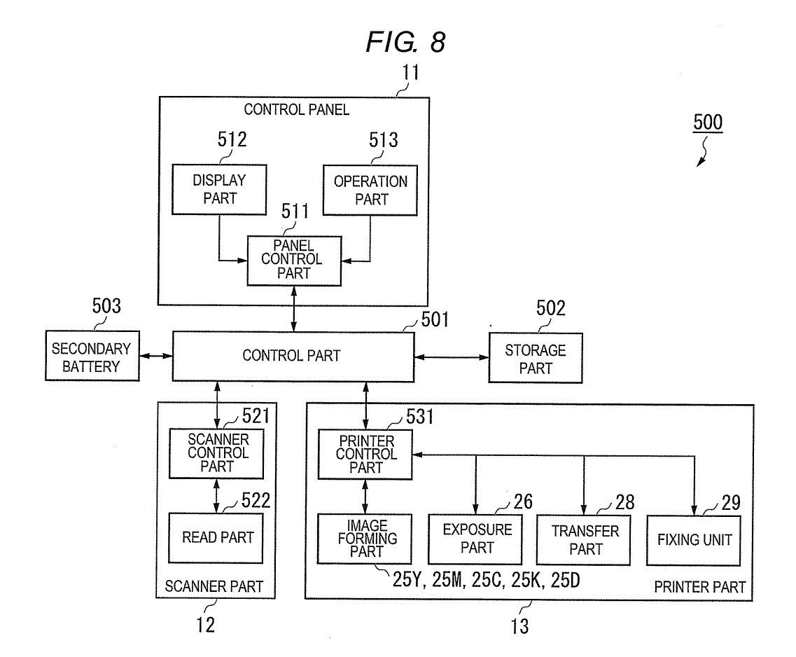

FIG. 8 is a block diagram showing a configuration example of the image forming apparatus 500 of the modified example of the embodiment. As shown in FIG. 8, the control panel 11, the scanner part 12 and the printer part 13 are connected to a control part 501. The control part 501 controls a CPU of each of the control panel 11, the scanner part 12 and the printer part 13 described later. The control part 501 controls the whole operation of the image forming apparatus 500. The control part 501 includes a CPU, a ROM and a RAM. The control part 501 is connected to a storage part 502 and a secondary battery 503. The control part 501 controls the power generation amount and the light transmittance of the photovoltaic element 400. The control part 501 automatically controls the photovoltaic element 400 according to control pattern data stored in the storage part 502. The control part 501 automatically controls the photovoltaic element 400 according to a user instruction signal outputted from the control panel 11.

The storage part 502 stores image information from the scanner part 12 or the outside. The storage part 502 is, for example, a hard disk device or a semiconductor memory. The storage part 502 stores various information required for control of the photovoltaic element 400.

The secondary battery 503 supplies a part of electric power required for the operation of the image forming apparatus 500. The secondary battery 503 applies DC voltage required for changing the light transmittance during dimming of the photovoltaic element 400 to the photovoltaic element 400. The secondary battery 503 stores generated power during power generation of the photovoltaic element 400.

The control panel 11 includes a panel control part 511, a display part 512 and an operation part 513. The panel control part 511 includes a CPU, a ROM and a RAM. The panel control part 511 controls the control panel 11.

The display part 512 outputs a screen corresponding to an operation content or an image corresponding to an instruction from the panel control part 511. The display part 512 outputs a screen corresponding to an operation content for the operation of the image forming apparatus 500.

The display part 512 displays various information relating to the power generation amount and the light transmittance of the photovoltaic element 400. The display part 512 outputs a screen corresponding to an operation content for the power generation amount and the light transmittance of the photovoltaic element 400.

The operation part 513 receives an operation from a user, and outputs a signal indicating the operation content to the panel control part 511. The operation part 513 includes various keys.

The display part 512 and the operation part 513 may be of a touch panel type in which the respective parts are integrally formed.

The panel control part 511 displays various information, such as the number of sheets to be printed, the size of the sheet S and the kind of the sheet S, on the display part 512. The operation part 513 receives designation and change of the information displayed by the display part 512. The operation part 513 receives, for example, designation of information indicating the kind of the sheet S. The operation part 513 outputs the designated information indicating the kind of the sheet S to the printer part 13.

The panel control part 511 displays, on the display part 512, various information relating to the power generation amount and the light transmittance of the photovoltaic element 400 and regarding an operation such as natural lighting or screening in the window of the building. The operation part 513 receives, for example, designation of information relating to the light transmittance of the whole photovoltaic element 400. The operation part 513 outputs the designated information relating to the light transmittance of the whole photovoltaic element 400 to the control part 501.

The scanner part 12 includes a scanner control part 521 and a read part 522. The scanner control part 521 includes a CPU, a ROM and a RAM. The scanner control part 521 controls reading of image information by the read part 522.

The printer part 13 includes a printer control part 531. The printer control part 531 includes a CPU, a ROM and a RAM. The printer control part 531 controls printing of an image to the sheet S by the printer part 13. The printer control part 531 writes various information designated by the control panel 11 into the built-in RAM.

In the photovoltaic system 100 of the modified example of the embodiment, since the image forming apparatus 500 is provided which controls the photovoltaic element 400, a dedicated controller and the like can be omitted. Since the control panel 11 is provided which inputs the user instruction to the control part 501, a dedicated controller or the like can be omitted. Since the image forming apparatus 500 as a business machine controls the photovoltaic element 400, the system configuration can be prevented from being complicated, and the cost required for the configuration can be prevented from increasing.

Hereinafter, other modified examples of the embodiment will be described.

Although the photoelectromotive force part 401 is the organic thin film solar cell in the photovoltaic element 400 of the embodiment, no limitation is made to this.

In a modified example of the embodiment, the photoelectromotive force part 401 may be an amorphous solar cell or a dye sensitized solar cell.

Although the first transmitting member 402 and the second transmitting member 403 are the electronic paper elements in the photovoltaic element 400 of the embodiment, no limitation is made to this.

In a modified example of the embodiment, the first transmitting member 402 and the second transmitting member 403 may be a transmission type liquid crystal element or the like. The transmission type liquid crystal element may be, for example, a guest-host type (GH type) liquid crystal element, a twisted nematic type (TN type) liquid crystal element, or a super twisted nematic (STN type) element. For example, the GH type liquid crystal element does not require a polarizing plate.

Although the color of the colored particle 409 is white in the photovoltaic element 400 of the embodiment, no limitation is made to this.

In a modified example of the embodiment, colors of the colored particles 409 of the first transmitting member 402 and the second transmitting member 403 may be the same or different from each other.

For example, in the photovoltaic element 400 arranged on a window of a building, the indoor side second transmitting member 403 may include the colored particle 409 having the same color as the color of an indoor wall surface.

In a modified example of the embodiment, color of each of the plural electronic paper elements 405 may be changeable. The color of each of the first transmitting member 402 and the second transmitting member 403 may be changed to an arbitrary color according to the preference of the user by the plural colors of the plural electronic paper elements 405.

In the photovoltaic element 400 of the embodiment, applied voltages to the plural transparent cells 406 of the electronic paper element 405 may be made the same or the applied voltage may be made different from each other. For example, light transmittances of the plural respective transparent cells 406 may be changed by changing the applied voltages to the plural respective transparent cells 406 of the electronic paper element 405. The light transmittance pattern of the whole photovoltaic element 400 may be changed according to the preference of the user by changing the light transmittances of the plural respective transparent cells 406 of the electronic paper element 405.

Although the photovoltaic element 400 of the embodiment is arranged on the window of the building or the moving body, no limitation is made to this.

In a modified example of the embodiment, the photovoltaic element 400 may be a window itself or a blind provided on a window, and further, may be a partition to divide a space.

Although the control part 501 of the image forming apparatus 500 controls the power generation amount and the light transmittance of the photovoltaic element 400 in the modified example of the embodiment described above, no limitation is made to this.

A control part to control the photovoltaic element 400 according to the user instruction outputted from the control panel 11 of the image forming apparatus 500 may be provided outside the image forming apparatus 500.

In the embodiment, the respective CPUs of the controller 200 and the image forming apparatus 500 may function by executing a program. The program may be recoded on a computer readable recording medium or may be transmitted through an electronic communication line. The recording medium is, for example, a flexible disk, a magneto-optical disk, a ROM, a portable medium such as a CD-ROM, or a storage device such as a hard disk incorporated in a computer system.

In the embodiment, all or a part of the function of the CPU of each of the controller 200 and the image forming apparatus 500 may be realized by hardware. The hardware is, for example, an LSI (Large Scale Integration), an ASIC (Application Specific Integrated Circuit), a PLD (Programmable Logic Device) or a FPGA (Field Programmable Gate Array).

According to at least one of the embodiments described above, since the first transmitting member 402 and the second transmitting member 403 are provided, the light transmittance can be set at both sides of the photoelectromotive force part 401 in the thickness direction. Since the first transmitting member 402 and the second transmitting member 403 are provided, the power generation amount and the light transmittance can be suitably set for the light incident from both sides of the photoelectromotive force part 401 in the thickness direction. Since the first transmitting member 402 and the second transmitting member 403 whose light transmittances are electrically changed independently of each other are provided, the power generation amount can be maximized while the constant light transmittance is kept as a whole.

While certain embodiments have been described these embodiments have been presented by way of example only, and are not intended to limit the scope of the inventions. Indeed, the novel embodiments described herein may be embodied in a variety of other forms: furthermore various omissions, substitutions and changes in the form of the embodiments described herein may be made without departing from the spirit of the inventions. The accompanying claims and there equivalents are intended to cover such forms or modifications as would fall within the scope and spirit of the invention.

What is claimed is:

1. A control method of photovoltaic element comprising:
preparing a photovoltaic element comprising a photoelectromotive force part, a first transmitting member, and a second transmitting member, the photoelectromotive force part having a light transmitting property and generating an electromotive force by light irradiation, the first transmitting member and the second transmitting member being arranged at both sides of the photoelectromotive force part in a thickness direction, light transmittances of the first transmitting member and the second transmitting member being electrically changed;
acquiring a user instruction for the light transmittance of the whole photovoltaic element;
adjusting the light transmittance at a light emission side in the first transmitting member and the second transmitting member according to the user instruction;
measuring change in power generation amount while changing the respective light transmittances of the first transmitting member and the second transmitting member; and
setting the respective light transmittances of the first transmitting member and the second transmitting member to values corresponding to the maximum power generation amount.

2. The control method of photovoltaic element according to claim 1, wherein
the light transmittances of the first transmitting member and the second transmitting member are electrically changed independently of each other.

3. The control method of photovoltaic element according to claim 1, wherein
the photovoltaic element is provided on a window of a building or a moving body while the first transmitting member is located at an outdoor side and the second transmitting member is located at an indoor side, and
when outdoor light is more intense than indoor light, the light transmittance is adjusted such that the light transmittance of the first transmitting member is increased and the light transmittance of the second transmitting member is decreased.

4. The control method of photovoltaic element according to claim 1, wherein
the photovoltaic element is provided on a window of a building or a moving body while the first transmitting member is located at an outdoor side and the second transmitting member is located at an indoor side, and
when indoor light is more intense than outdoor light, the light transmittance is adjusted such that the light transmittance of the first transmitting member is decreased and the light transmittance of the second transmitting member is increased.

5. The control method of photovoltaic element according to claim 1, wherein
an input part is used when the user instruction is acquired.

6. The control method of photovoltaic element according to claim 1, wherein
the photoelectromotive force part has sensitivity in a wavelength range including wavelengths of sun light and illumination light.

7. The control method of photovoltaic element according to claim 1, wherein
the photoelectromotive force part has an organic thin film solar cell.

8. The control method of photovoltaic element according to claim 5, wherein
in at least one of:
a case where a signal to instruct setting of the light transmittance of the whole photovoltaic element is inputted from the input part;
a case where a specified time passes after the respective light transmittances of the first transmitting member and the second transmitting member are set; and
a case where the power generation amount of the photovoltaic element changes more than a specified value,
the power generation amount of the photovoltaic element is maximized by changing the respective light transmittances of the first transmitting member and the second transmitting member while keeping the light transmittance of the whole photovoltaic element constant.
